(19) United States
(12) Patent Application Publication
(10) Pub. No.: US 2010/0307560 A1
(43) Pub. Date: Dec. 9, 2010

(54) SELF-REMEDIATING PHOTOVOLTAIC MODULE

(75) Inventors: Christopher Baker, Maumee, OH (US); Karina Krawczyk, Perrysburg, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/793,333

(22) Filed: Jun. 3, 2010

Related U.S. Application Data
(60) Provisional application No. 61/183,849, filed on Jun. 3, 2009.

(51) Int. Cl. H01L 31/042; H01L 31/02; H01L 31/18

(52) U.S. Cl. 136/244; 136/252; 438/64; 438/98; 257/E31.117; 257/E31.11

(57) ABSTRACT

A method for manufacturing a photovoltaic module can include depositing a heavy metal-immobilizing agent proximate to one or more components of a photovoltaic module.

### CLAIM FOR PRIORITY

This application claims priority under 35 U.S.C. §119(e) to U.S. Provisional Patent Application Ser. No. 61/183,849 filed on Jun. 3, 2009, which is hereby incorporated by reference.

### TECHNICAL FIELD

The present invention relates to photovoltaic modules and methods of production.

### BACKGROUND

Photovoltaic modules can include semiconductor material deposited over a substrate, for example, with a first layer serving as a window layer and a second layer serving as an absorber layer. The semiconductor window layer can allow the penetration of solar radiation to the absorber layer, such as a cadmium telluride layer, which converts solar energy to electricity. Photovoltaic modules can also contain one or more transparent conductive oxide layers, which are also often conductors of electrical charge.

### DESCRIPTION OF DRAWINGS

FIG. 1 is a schematic of a photovoltaic module.

FIG. 2 is a schematic of a photovoltaic module with an encapsulation frame.

FIG. 3 is a schematic of a photovoltaic module.

FIG. 4 is a schematic of a photovoltaic module with an encapsulation frame.

FIG. 5 is a schematic of a photovoltaic module with an encapsulation frame.

FIG. 6 is a schematic of a photovoltaic module and cord plate.

FIG. 7 is a schematic of a photovoltaic module and cord plate.

FIG. 8 is a schematic of a photovoltaic module and cord plate.

### DETAILED DESCRIPTION

Photovoltaic devices can include multiple layers created on a substrate (or superstrate). For example, a photovoltaic device can include a barrier layer, a transparent conductive oxide (TCO) layer, a buffer layer, and a semiconductor layer formed in a stack on a substrate. Each layer may in turn include more than one layer or film. For example, the semiconductor layer can include a first film including a semiconductor window layer, such as a cadmium sulfide layer, formed on the buffer layer and a second film including a semiconductor absorber layer, such as a cadmium telluride layer formed on the semiconductor window layer. Additionally, each layer can cover all or a portion of the device and/or all or a portion of the layer or substrate underlying the layer. For example, a “layer” can include any amount of any material that contacts all or a portion of a surface.

Photovoltaic modules can be formed on optically transparent substrates, such as glass. Because glass is not conductive, a transparent conductive oxide (TCO) layer is typically deposited between the substrate and the semiconductor bi-layer. Cadmium stannate functions well in this capacity, as it exhibits high optical transmission and low electrical sheet resistance. A smooth buffer layer can be deposited between the TCO layer and the semiconductor window layer to decrease the likelihood of irregularities occurring during the formation of the semiconductor window layer. Additionally, a barrier layer can be incorporated between the substrate and the TCO layer to lessen diffusion of sodium or other contaminants from the substrate to the semiconductor layers, which could result in degradation and delamination. The barrier layer can be transparent, thermally stable, with a reduced number of pin holes and having high sodium-blocking capability, and good adhesive properties. Therefore the TCO can be part of a three-layer stack, which may include, for example, a silicon dioxide barrier layer, a cadmium stannate TCO layer, and a buffer layer (e.g., a tin (IV) oxide). The buffer layer can include various suitable materials, including tin oxide, zinc tin oxide, zinc oxide, and zinc magnesium oxide. A photovoltaic module can include a cadmium sulfide window layer deposited over a TCO stack and a cadmium telluride absorber layer deposited over the cadmium sulfide layer. Cadmium telluride photovoltaic modules offer several advantages over other photovoltaic technologies. Among those are superior light absorption properties under cloudy and diffuse light conditions and ease of manufacturing.

The cadmium telluride thin film layer can be encapsulated within the module by materials designed to seal and hold the module together for many years and under a variety of conditions. The encapsulation material can help retain heavy metals present within the module by forming low solubility compounds that immobilize, chelate, adsorb, and/or fixate the cadmium and/or other heavy metals within the structure of the module to assist with handling and disposal.

A bus bar assembly may be attached to a contact surface of a photovoltaic module to enable connection to additional electrical components (e.g., one or more additional modules). For example, a first strip of double-sided tape may be distributed along a length of the module, and a first lead foil may be applied adjacent thereto. A second strip of double-sided tape (smaller than the first strip) may be applied adjacent to the first lead foil. A second lead foil may be applied adjacent to the second strip of double-sided tape. The tape and lead foils may be positioned such that at least one portion of the first lead foil is exposed, and at least one portion of the second lead foil is exposed. Following application of the tape and lead foils, a plurality of bus bars may be positioned along the contact region of the module. The bus bars may be positioned parallel from one another, at any suitable distance apart. For example, the plurality of bus bars may include at least one bus bar positioned on a portion of the first lead foil, and at least one bus bar positioned on a portion of the second lead foil. The bus bar, along with the portion of lead foil on which it has been applied, may define a positive or negative region. A roller may be used to create a loop in a section of the first or second lead foil. The loop may be threaded through the hole of a subsequently deposited back glass. The photovoltaic module may be connected to other electronic components, including, for example, one or more additional photovoltaic modules. For example, the photovoltaic module may be electrically connected to one or more additional photovoltaic modules to form a photovoltaic array.

The photovoltaic modules/arrays may be included in a system for generating electricity. For example, a photovoltaic module may be illuminated with a beam of light to generate a photocurrent. The photocurrent may be collected and converted from direct current (DC) to alternating current (AC) and distributed to a power grid. Light of any suitable wavelength may be directed at the cell to produce the photocurrent, including, for example, more than 400 nm, or less than 700 nm (e.g., ultraviolet light). Photocurrent generated from one photovoltaic module may be combined with photocurrent generated from other photovoltaic modules. For example, the photovoltaic modules may be part of a photovoltaic array, from which the aggregate current may be harnessed and distributed.

In one aspect, a method for manufacturing a photovoltaic module can include depositing a heavy metal-immobilizing agent proximate to one or more components of a photovoltaic module.

The one or more components can include a heavy metal. The heavy metal-immobilizing agent can include a precipitating agent, a complexing agent, a sorbent, or a stabilization agent.

The heavy metal may include cadmium. The precipitating agent may include a sulfide, hydroxide, carbonate, phosphate, or silicate, or combinations thereof. The precipitating agent may include a calcium phosphate, a calcium sulfide, or a calcium carbonate, or combinations thereof. The complexing agent may include a nitrogen-containing group, a sulfur-containing group, a phosphorus-containing group, an acid group, a carbonyl group, or combinations thereof. The complexing agent may also include EDTA, cysteine, xanthates, trimercaptotriazine, or di-n-propyldithiophosphate, or combinations thereof. The complexing agent may include an ion exchange resin, beads, or membrane. The sorbent may include zeolites, metal oxides, zero valent iron, carbon, tannin-rich materials, modified natural fibers, and modified synthetic fibers. The sorbent may also include an apatite, a clay, or an oxide, or any combination thereof. The stabilization agent may include a cementious material.

The depositing may include depositing the heavy metal-immobilizing agent on a heavy metal-containing layer. The depositing may include depositing the immobilizing agent in the laser scribes of a heavy metal. The heavy metal-immobilizing agent may be part of a base chain of a polymeric adhesive or interlayer material. The heavy metal-immobilizing agent may include one or more functional groups. The depositing may include dispersing the heavy metal-immobilizing agent throughout an interlayer near a polymer-metal interface. The method may include laminating one or more layers, where the photovoltaic module includes the one or more layers. The depositing may include dispersing the heavy metal-immobilizing agent as a powder onto a metal layer prior to interlayer placement or lamination. The depositing may include patterning the deposition of the heavy metal-immobilizing agent onto a metal layer surface. The depositing may include dispersing the heavy metal-immobilizing agent as a powder onto a barrier layer surface prior to interlayer placement or lamination. The depositing may include patterning deposition of the heavy metal immobilizing agent onto a barrier layer surface. The depositing may include dispersing the heavy metal-immobilizing agent in a solution and spraying the solution onto a metal layer prior to interlayer placement or lamination. The depositing may include dispersing the heavy metal-immobilizing agent in a solution and rolling the solution onto a metal layer prior to interlayer placement or lamination. The depositing may include dispersing the heavy metal-immobilizing agent in a solution and patterning the solution onto a metal layer prior to interlayer placement or lamination. The depositing may include dispersing the immobilizing agent in solution and spraying the solution onto a barrier layer prior to interlayer placement or lamination. The depositing may include dispersing the heavy metal-immobilizing agent in solution and rolling the solution onto a barrier layer prior to interlayer placement or lamination. The depositing may include dispersing the heavy metal-immobilizing agent in solution and patterning the solution onto a barrier layer prior to interlayer placement or lamination. The depositing may include dispersing the heavy metal-immobilizing agent in solution and spraying the solution onto either side of a back or front support. The depositing may include dispersing the heavy metal-immobilizing agent in solution and rolling the solution onto either side of a back or front support. The depositing may include dispersing the heavy metal-immobilizing agent in solution and patterning the solution onto either side of a back or front support. The depositing may include dispersing the heavy metal-immobilizing agent in a solution and screen-printing the solution onto a metal layer prior to interlayer placement or lamination. The depositing may include dispersing the immobilizing agent in a solution and screen-printing the solution onto a barrier layer prior to interlayer placement or lamination. The solution can include a solvent. The solution can be water-based. The method can include adjusting the viscosity of the solution to an appropriate viscosity for spray application. The method can include adjusting the viscosity of the solution to an appropriate viscosity for screen-printed application. The method can include drying the heavy metal-immobilizing agent. The depositing can include depositing the heavy metal-immobilizing agent proximate to one or more interlayers. The method can include immersing an interlayer material in a solution containing the heavy metal-immobilizing agent. The depositing can include spin-coating the heavy metal-immobilizing agent onto a metal layer prior to interlayer placement or lamination. The method can include drying the heavy metal-immobilizing agent. The method can include encapsulating the photovoltaic module in a frame. The one or more components can include a magnesium telluride back contact metal. The one or more components can include solder proximate to a cord plate. The solder can include lead. The method can include remediating the cord plate by contacting the solder with a flowable sealant including the heavy metal-immobilizing agent.

In one aspect, a photovoltaic module can include a heavy metal-immobilizing agent proximate to one or more components of a photovoltaic module. The one or more components can include a heavy metal. The heavy metal-immobilizing agent can include a precipitating agent, a complexing agent, a sorbent, or a stabilization agent. The heavy metal can include cadmium. The precipitating agent can include a sulfide, hydroxide, carbonate, phosphate, or silicate, or combinations thereof. The precipitating agent can include calcium carbonate, calcium hydroxide, calcium phosphate, calcium sulfide, or combinations thereof. The complexing agent can include a nitrogen-containing group, sulfur-containing group, phosphorus-containing group, acid group, carbonyl group, or combinations thereof. The complexing agent can include EDTA. The complexing agent can include cysteine, xanthates, trimercaptotriazine, or combinations thereof. The complexing agent can include an ion exchange resin, beads, or membrane. The sorbent can include zeolites, metal oxides, zero valent iron, carbon, tannin-rich materials, modified natural fibers, modified synthetic fibers, or combinations thereof. The sorbent can also include an apatite, a clay, an oxide, a cementious material, or combinations thereof. The heavy metal-immobilizing agent can be part of a base chain of a polymeric adhesive or interlayer material. The heavy metal-immobilizing agent can include a functional group. The one or more components can include a magnesium telluride back contact metal. The one or more components can include solder proximate to a cord plate. The solder can include lead. The solder at the cord plate can be remediated by contacting the solder with a flowable sealant including the heavy metal-immobilizing agent.

The one or more components can include a plurality of photovoltaic cells adjacent to a substrate. The one or more components can include a back cover adjacent to the plurality of photovoltaic cells. Each one of the plurality of photovoltaic cells may include a contact layer. The photovoltaic module may include a first strip of tape having a length distributed along each contact layer. The first strip of tape may include a front surface and a back surface. Each surface may contain an adhesive. The photovoltaic module may include a first lead foil distributed along the length of the first strip of tape. The photovoltaic module may include a second strip of tape, having a length shorter than that of the first strip of tape, distributed along the length and between the ends of the first strip of tape. The second strip of tape may include a front and back surface. Each surface may contain an adhesive. The photovoltaic module may include a second lead foil, having a length shorter than that of the second strip of tape, distributed along the length of the second strip of tape. The photovoltaic module may include a plurality of parallel bus bars, positioned adjacent and perpendicular to the first and second strips of tape. Each one of the plurality of parallel bus bars may contact one of the first or second lead foils. The photovoltaic module may include first and second submodules. The first submodule may include two or more cells of the plurality of photovoltaic cells connected in series. The second submodule may include another two or more cells of the plurality of photovoltaic cells connected in series. The first and second submodules may be connected in parallel through a shared cell.

In one aspect, a method for generating electricity may include illuminating a photovoltaic module with a beam of light to generate a photocurrent. The method may include collecting the generated photocurrent. The photovoltaic module may include a heavy metal-immobilizing agent proximate to one or more components.

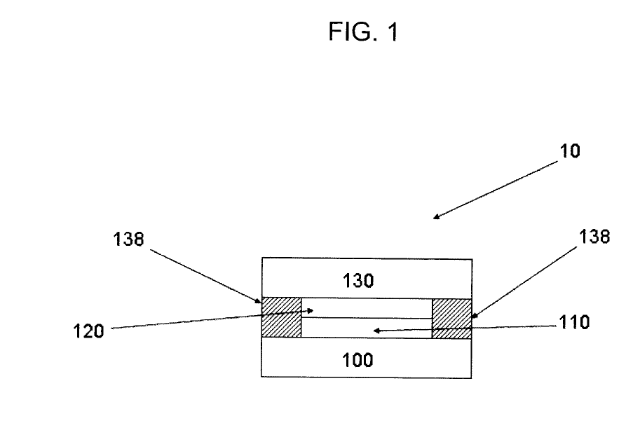

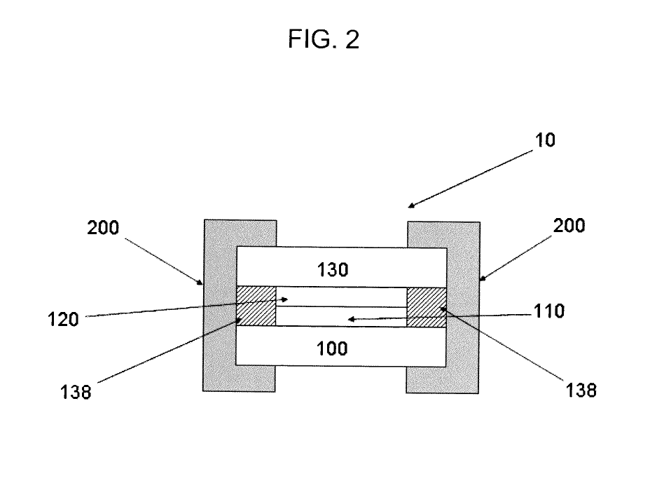

Referring to FIG. 1, a self-remediating photovoltaic module 101 can include a front support 100 and a back support 130. Front support 100 and back support 130 can include any suitable material, including glass, for example, soda-lime glass. One or more layers 110 can be deposited adjacent to front support 100, which can serve as a first substrate, on top of which various layers may be added. Layer(s) 110 can include one or more device layers. For example, layer(s) 110 can include a cadmium telluride absorber layer adjacent to a cadmium sulfide window layer. Layer (s) 110 can include additional metal layers adjacent to the cadmium telluride absorber layer. One or more metal-immobilizing agents can be deposited adjacent to layer(s) 110. For example, a heavy metal-immobilizing agent 120 can be deposited adjacent to layer(s) 110. Heavy metal-immobilizing agent 120 can include a precipitating agent, a complexing agent, a sorbent, or a stabilizing agent. The precipitating agent can include various suitable materials, including FeS, Na₂S, CaS, Ca(OH)₂, NaOH, CaHPO₄, Ca(H₂PO₄)₂, CaCO₃, CaSiO₃, or a combination thereof. The complexing agent can include various suitable materials. For example, the complexing agent can include imino groups, thiol groups, disulfides, carbamates, or acid groups. Examples include, but are not limited to, EDTA, cysteine, xanthates, trimercaptotriazines, di-n-propyldithiophosphates, or any combination thereof. Possible sorbents include, but are not limited to, zeolites (synthetic or natural, modified or non-modified), lignin, chitosan, dead biomass, fly ash, clay, apatite, metal oxides (hydrous or non-hydrous), zero valent iron, carbon, tannin-rich materials, or combinations thereof. The stabilization material can include a cementious material such as pozzolan Photovoltaic module 10 can include one or more interlayers 138, positioned adjacent to layer(s) 110 and front and back supports 100 and 130. The heavy metal-immobilizing agent 120 can also be deposited within the laser scribes of any of layer(s) 110, or on either side of the front and back supports. Referring to FIG. 2, an encapsulation frame 200 can be placed around photovoltaic module 10 to hold the module layers together.

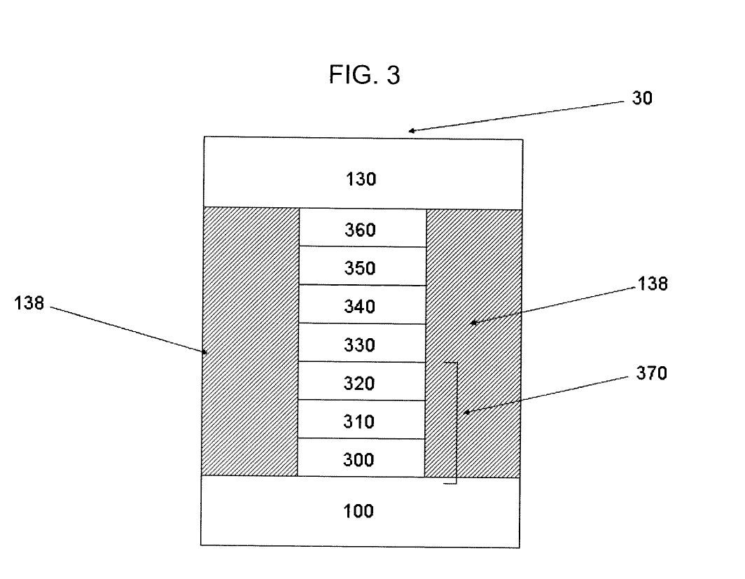

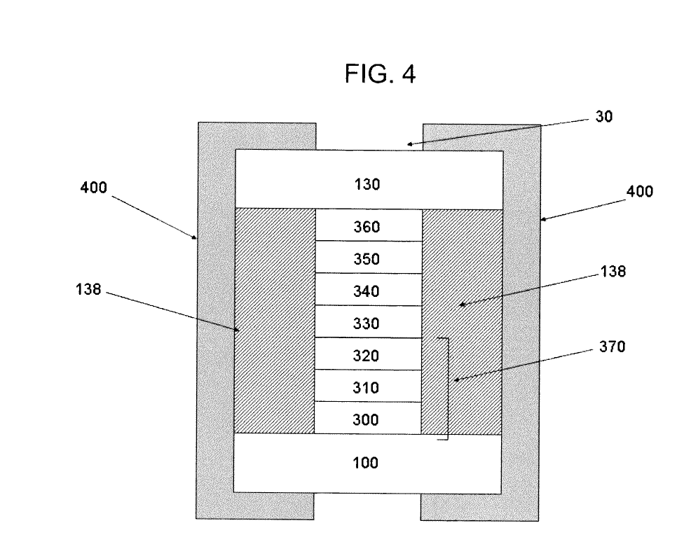

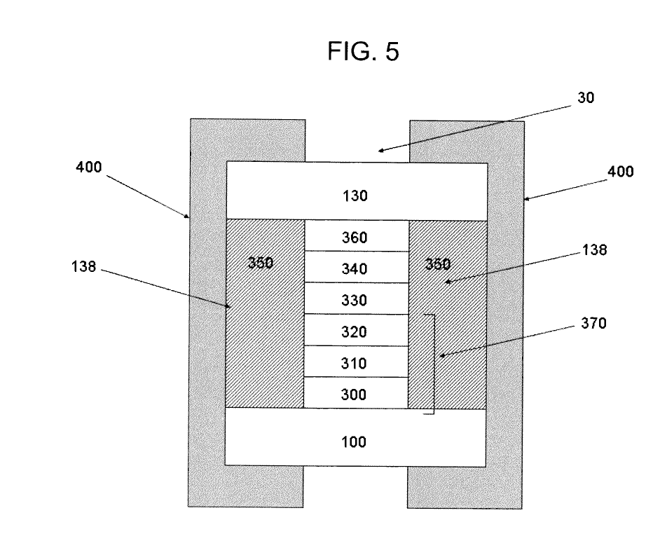

Referring to FIG. 3, a photovoltaic module 30 can include a heavy metal-immobilizing agent 350 directly adjacent to cadmium telluride layer 340. A photovoltaic module 30 can include a heavy metal-immobilizing agent directly adjacent to another metal layer or a barrier layer 350. Photovoltaic module 30 can include a barrier layer 300 adjacent to substrate 100. Transparent conductive oxide layer 310 can be deposited adjacent to barrier layer 300. A buffer layer 320 can be deposited adjacent to transparent conductive oxide layer 310. Barrier layer 300, transparent conductive oxide layer 310, and buffer layer 320 can be deposited using any suitable deposition technique, including sputtering. Substrate 100, barrier layer 300, transparent conductive oxide layer 310, and buffer layer 320 can be part of a transparent conductive oxide stack 370, which can be annealed prior to the deposition of subsequent layers. Cadmium sulfide layer 330 can be deposited adjacent to transparent conductive oxide stack 370 after annealing. Cadmium telluride layer 340 can be deposited onto cadmium sulfide layer 330. Cadmium sulfide layer 330 and cadmium telluride layer 340 can be deposited using any suitable deposition technique, including vapor transport deposition. One or more additional metal layers can be deposited adjacent to cadmium telluride layer 340. For example, a back contact metal 350 can be deposited adjacent to cadmium telluride layer 340. Back contact metal 350 can be deposited using any suitable deposition technique, including sputtering. Heavy metal-immobilizing agent 360, which can include a precipitating agent, a complexing agent, a sorbent, or a stabilizing agent, can be deposited adjacent to cadmium telluride layer 340 or adjacent to back contact metal 350. Heavy metal-immobilizing agent 360 can also be suitable for immobilizing other metals, such as mercury or lead. Heavy metal-immobilizing agent 360 can be deposited on a barrier layer. The barrier layer can be placed adjacent to a heavy metal-containing layer or adjacent to one or more additional metal layers. The barrier layer can also be patterned, and the heavy metal-immobilizing agent can be selectively placed on the barrier layer. The barrier layer can be a polymer or a ceramic and deposited by suitable means. Heavy metal-immobilizing agent 360 can also be deposited within cadmium telluride layer 340 within the laser scribes. Referring to FIG. 5, a heavy metal-immobilizing agent can also be deposited as part of an interlayer 138 between front support 100 and back support 130, adjacent to one or more intermediate layers (i.e., layer(s) 110 from FIG. 1). Interlayer 138 can include any suitable interlayer material, including for example, a heavy metal-immobilizing agent. Referring to FIG. 4, heavy metal-immobilizing agent 360 can be deposited directly onto cadmium telluride layer 340 or deposited directly onto back contact metal 350. The heavy metal-immobilizing agent can necessitate the development of a new process for recycling the materials of photovoltaic modules.

Heavy metal-immobilizing agent 360 can be deposited using any suitable technique. For example, heavy metal-immobilizing agent 360 can be dispersed as a powder onto cadmium telluride layer 340 or onto back contact metal 350. Heavy metal-immobilizing agent 360 can be patterned onto the surface of cadmium telluride layer 340 or back contact metal 350. Heavy metal-immobilizing agent 360 can be dispersed as a powder onto a barrier material adjacent to the cadmium telluride layer 340 or onto the metal layer 350. Heavy metal-immobilizing agent 360 can be dispersed in a solution and sprayed onto cadmium telluride layer 340 or back contact metal 350 prior to interlayer placement or lamination. The solution can be a solvent, or it can be water-based; and the viscosity of the solution can be adjusted to achieve a suitable level of viscosity for spray and/or screen-printed application. Heavy metal-immobilizing agent 360 can be screen-printed onto cadmium telluride layer 340 or back contact metal 350 prior to interlayer placement or lamination. Heavy metal-immobilizing agent 360 can undergo a drying process. Photovoltaic module 30 can be encapsulated in frame 400 from FIGS. 4 and 5.

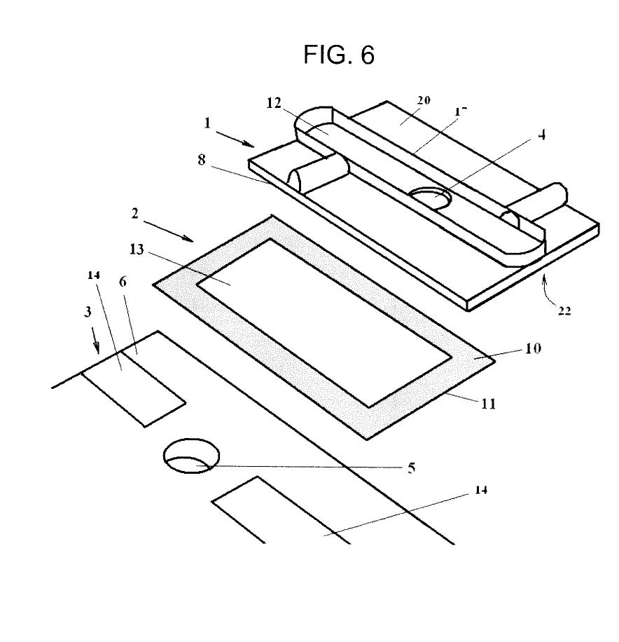

A heavy metal-immobilizing agent can also be suitable for immobilizing other heavy metals present within the module, including cord plate solder. For example, referring to FIG. 6, cover plate or back support 130 has first surface 6. Back support 130 can include a connector 5. Connector 5 can be any suitable connector, such as a hole formed in back support 130. Connector 5 can be an impression formed in first surface 6 of back support 130. Connector 5 can be connected to the photovoltaic device of the photovoltaic module. The heavy metal-immobilizing agent can be included in a component of the cord plate assembly, such as a flowable sealant. Suitable cord plates are described, for example, in U.S. Application No. 61/159,504 filed Mar. 12, 2009, which is incorporated by reference in its entirety.

Conductor 14 can be adjacent to first surface 6 of back support 130. For example, conductor 14 can be a foil strip positioned substantially in the plane of first surface 6. Conductor 14 can be a lead foil strip. Conductor 14 can include a first end (not shown) connected to photovoltaic devices provided on the photovoltaic module. There can be multiple conductors 14. Conductor 14 can include a second end positioned on first surface 6 of back support 130. The second end of connector 14 can be positioned proximate to connector 5.

In continuing reference to FIG. 6, cord plate 1 includes a base 8. Base 8 can be rectangular or any other shape suitable for positioning and sealing cord plate 1 adjacent to first surface 6 of back support 130. Base 8 can include a top surface 20 and a bottom surface 22, which can be formed as suitable to cooperate and adhere to first surface 6 of back support 130. For example, bottom surface 22 of base 8 can be flat. Bottom surface 22 of base 8 can be recessed. Bottom surface 22 can be primed by preparing the first surface of cord plate with flame treatment, abrasion, or solvent preparation. A flame treatment applied to bottom surface 22 can alter the surface energy or wettability of bottom surface 22 and can increase adhesion. Treatment with a primer or a primer/flame treatment combination can also alter the surface energy or wettability of bottom surface 22 and can increase adhesion. For example, bottom surface 22 of base 8 can be primed with an organo-silane primer or any other suitable primer. Cord plate 1 includes channel 4, which can be an opening formed in base 8, i.e., an opening from top surface 20 to bottom surface 22. Channel 4 is configured to receive a flowable sealant. Channel 4 can be an opening formed by milling a hole through base 8 of cord plate 1. Channel 4 can also be formed by injection molding. Channel 4 can also include partition 17 extending from top surface 20 of base 8. Partition 17 can encircle the hole in base 8 to define a compartment 12 into which a flowable sealant can be received. Cord plate 1 can be any suitable material, including any suitable plastic or polycarbonate, such as LEXAN500. Cord plate 1 can be any suitable color, and can be transparent.

As shown in FIG. 6, cord plate 1 can be positioned proximate to back support 130 in preparation for adhering bottom surface 22 of cord plate 1 to first surface 6 of back support 130. In this manner, cord plate 1 can be moved into a position adjacent to and in contact with first surface 6 of back support 130. Alternatively, seal 2 can be positioned between first surface 6 of back support 130 and bottom surface 22 of cord plate 1. Seal 2 can position and adhere cord plate 1 in preparation for a robust, installation-caliber seal. Seal 2 can include a very high bond (VHB) material, including an acrylic foam, for example an acrylic foam core 11. Seal 2 can have an opening 13 that allows channel 4 to be positioned over and in fluid communication with connector 5. Seal 2 can include an adhesive, such as a pressure sensitive adhesive (PSA) applied to a surface of seal 2 that will contact first surface 6 of back support 130, bottom surface 22 of cord plate 1, or both. Seal 2 can be shaped substantially similarly to base 8 of cord plate 1. For example, seal 2 can be a rectangle.

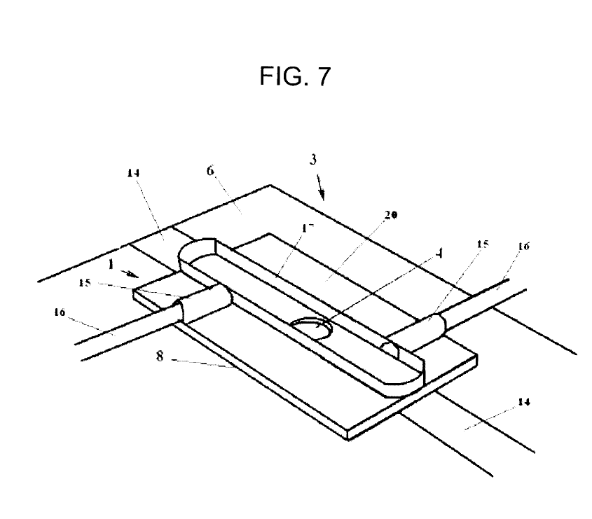

Referring to FIG. 7, cord plate 1 is positioned adjacent to back support 130, with seal 2 (FIG. 6) optionally positioned between cord plate 1 and back support 130. Cord plate 1 is positioned such that channel 4 is positioned over, and in fluid communication with, connector 5 (not shown). For example, channel 4 and connector 5 can include holes of similar diameter, in which case the hole included in channel 4 can be positioned directly over the congruous connector 5 hole. Channel 4 can also be positioned partially, but not completely, over connector 5.

In continuing reference to FIG. 7, when cord plate 1 is positioned adjacent to first surface 6 of back support 130, a space is defined by back support 130, connector 5 and portions of cord plate 1, including bottom surface 22 (whether recessed or not) and channel 4 (including partition 17 and the portion of top surface 20 included in the partition included in channel 4, if any). This space is in fluid communication, and can include additional space defined by opening 13 of seal 2, if seal 2 is included in the assembly.

As shown in FIG. 7, cord plate 1 includes junction 15, which can be a receptacle formed on top surface 22 of cord plate 1 and configured to position and intersect a second conductor 16 with conductor 14. Second conductor can include insulated electrical wiring for carrying electrons either to or from conductor 14, depending on whether junction 15 is a “positive” junction or a “negative” junction (cord plate 1 can include each type of junction). As shown in FIG. 7, junction 15 can be used to position and secure second conductor 16 proximate to conductor 14. After they are correctly positioned, conductor 14 and second conductor 16 can be connected, for example, by soldering. A heavy metal-immobilizing agent can be positioned proximate to the solder connecting conductor 14 and second conductor 16 to immobilize the solder.

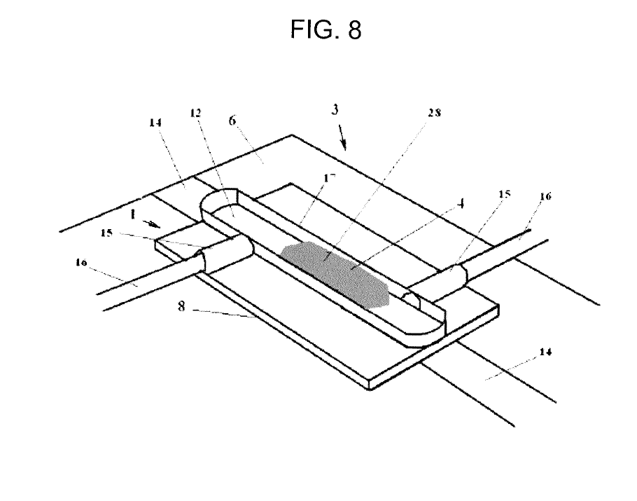

Second conductor 16 can be positioned in junction 15 either before or after cord plate 1 is positioned adjacent to first surface 6 of back support 130. Referring to FIG. 8, flowable sealant 28 is introduced into and received by channel 4 and components thereof, including compartment 12 defined by partition 17 and the portion of top surface 20 contained therein, and the underlying hole formed in base 8 (not shown). Flowable sealant 28 can be any suitable sealant, including a low-viscosity sealant. Flowable sealant 28 can be a one-component sealant, a two-component sealant, or higher-component sealant. Flowable sealant can include any suitable substance, including silicone, acrylic, polysulfide, a butyl sealant, a one part or two part polyurethane sealant, or any other sealant capable of robustly sealing cord plate 1 to back support 130.

Flowable sealant 28 flows through channel 4 into the space defined by the bottom surface 22 of cord plate 1, back support 130, connector 5 and seal 2 (if present). In this manner, flowable sealant 28 contacts channel 4, back support 130 and connector 5 and any other component in fluid communication with channel 4 into which flowable sealant 28 has been introduced. Flowable sealant 28 can then cure to engage and adhere cord plate 1 and back support 130 and potentially other components flowable sealant contacts.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A method for manufacturing a photovoltaic module, the method comprising:
depositing a heavy metal-immobilizing agent proximate to one or more components of a photovoltaic module.

2. The method of claim 1, wherein the one or more components comprises a heavy metal.

3. The method of claim 2, wherein the heavy metal immobilizing agent comprises a precipitating agent, a complexing agent, a sorbent, or a stabilization agent, wherein:
the precipitating agent is selected from the group consisting of sulfide, hydroxide, carbonate, phosphate, and silicate;
the complexing agent includes a nitrogen-containing group, a sulfur-containing group, a phosphorus-containing group, an acid group, a carbonyl group, EDTA, a cysteine, a xanthate, a trimercaptotriazine, a di-n-propyldithiophosphate, an ion exchange resin, a bead, or a membrane;
the sorbent is selected from the group consisting of zeolites, apatites, clay, oxides, metal oxides, zero valent iron, carbon, tannin-rich materials, modified natural fibers, and modified synthetic fibers;
the stabilization agent includes a cementious material; or
the heavy metal-immobilizing agent is part of a base chain of a polymeric adhesive or interlayer material, optionally including a functional group.

4. The method of claim 1, wherein the depositing comprises:
depositing the heavy metal-immobilizing agent on a heavy metal-containing layer;
depositing the heavy metal-immobilizing agent in the laser scribes of a heavy metal; or
dispersing the heavy metal-immobilizing agent throughout an interlayer near a polymer-metal interface.

5. The method of claim 1, further comprising laminating one or more layers, wherein the photovoltaic module comprises the one or more layers.

6. The method of claim 1, wherein the depositing comprises dispersing the heavy metal-immobilizing agent as a powder onto a metal layer prior to interlayer placement or lamination.

7. The method of claim 6, wherein the depositing further comprises patterning the deposition of the heavy metal-immobilizing agent onto a metal layer surface.

8. The method of claim 1, wherein the depositing comprises dispersing the heavy metal-immobilizing agent as a powder onto a barrier layer surface prior to interlayer placement or lamination.

9. The method of claim 8, wherein the depositing further comprises patterning deposition of the heavy metal-immobilizing agent onto a barrier layer surface.

10. The method of claim 1, wherein the depositing comprises:
dispersing the heavy metal-immobilizing agent in a solution and spraying the solution onto a metal layer prior to interlayer placement or lamination;
dispersing the heavy metal-immobilizing agent in a solution and rolling the solution onto a metal layer prior to interlayer placement or lamination;
dispersing the heavy metal-immobilizing agent in a solution and patterning the solution onto a metal layer prior to interlayer placement or lamination;
dispersing the heavy metal-immobilizing agent in solution and spraying the solution onto a barrier layer prior to interlayer placement or lamination;
dispersing the heavy metal-immobilizing agent in solution and rolling the solution onto a barrier layer prior to interlayer placement or lamination;
dispersing the heavy metal-immobilizing agent in solution and patterning the solution onto a barrier layer prior to interlayer placement or lamination;
dispersing the heavy metal-immobilizing agent in solution and spraying the solution onto either side of a back support;
dispersing the heavy metal-immobilizing agent in solution and rolling the solution onto either side of a back or front support;
dispersing the heavy metal-immobilizing agent in solution and patterning the solution onto either side of a back or front support;
dispersing the heavy metal-immobilizing agent in a solution and screen-printing the solution onto a metal layer prior to interlayer placement or lamination; or
dispersing the immobilizing agent in a solution and screen-printing the solution onto a barrier layer prior to interlayer placement or lamination.

11. The method of claim 1, wherein the depositing comprises depositing the heavy metal-immobilizing agent proximate to one or more interlayers.

12. The method of claim 1, further comprising immersing an interlayer material in a solution containing the heavy metal-immobilizing agent.

13. The method of claim 1, wherein the depositing comprises spin-coating the heavy metal-immobilizing agent onto a metal layer prior to interlayer placement or lamination.

14. The method of claim 13, further comprising drying the heavy metal-immobilizing agent.

15. The method of claim 1, further comprising encapsulating the photovoltaic module in a frame.

16. The method of claim 15, further comprising remediating solder by contacting the solder with a flowable sealant including the heavy metal-immobilizing agent.

17. A photovoltaic module comprising a heavy metal-immobilizing agent proximate to one or more components of a photovoltaic module.

18. The photovoltaic module of claim 17, wherein the one or more components comprises a heavy metal.

19. The photovoltaic module of claim 18, wherein the heavy metal comprises cadmium.

20. The photovoltaic module of claim 19, wherein the heavy metal-immobilizing agent includes a precipitating agent, a complexing agent, a sorbent, or a stabilization agent, wherein:
the precipitating agent is selected from the group consisting of sulfide, hydroxide, carbonate, phosphate, and silicate;
the complexing agent includes a nitrogen-containing group, a sulfur-containing group, a phosphorus-containing group, an acid group, a carbonyl group, EDTA, a cysteine, a xanthate, a trimercaptotriazine, a di-n-propyldithiophosphate, an ion exchange resin, a bead, or a membrane;
the sorbent is selected from the group consisting of zeolites, apatites, clay, oxides, metal oxides, zero valent iron, carbon, tannin-rich materials, modified natural fibers, and modified synthetic fibers;
the stabilization agent includes a cementious material; or
the heavy metal-immobilizing agent is part of a base chain of a polymeric adhesive or interlayer material, optionally including a functional group.

21. The photovoltaic module of claim 17, wherein the one or more components comprises:
a plurality of photovoltaic cells adjacent to a substrate; and
a back cover adjacent to the plurality of photovoltaic cells, each one of the plurality of photovoltaic cells comprising a contact layer.

22. The photovoltaic module of claim 21, further comprising:
a first strip of tape having a length distributed along each contact layer, the first strip of tape comprising a front surface and a back surface, each surface containing an adhesive;
a first lead foil distributed along the length of the first strip of tape;
a second strip of tape, having a length shorter than that of the first strip of tape, distributed along the length and between the ends of the first strip of tape, wherein the second strip of tape comprises a front and back surface, each containing an adhesive;
a second lead foil, having a length shorter than that of the second strip of tape, distributed along the length of the second strip of tape; and
a plurality of parallel bus bars, positioned adjacent and perpendicular to the first and second strips of tape, wherein each one of the plurality of parallel bus bars contacts one of the first or second lead foils.

23. The photovoltaic module of claim 22, further comprising first and second submodules, wherein the first submodule comprises two or more cells of the plurality of photovoltaic cells connected in series, and the second submodule comprises another two or more cells of the plurality of photovoltaic cells connected in series, wherein the first and second submodules are connected in parallel through a shared cell.

24. A method for generating electricity, the method comprising:
illuminating a photovoltaic module with a beam of light to generate a photocurrent; and
collecting the generated photocurrent, wherein the photovoltaic module comprises a heavy metal-immobilizing agent proximate to one or more components.
